(19) United States
(12) Patent Application Publication
(10) Pub. No.: US 2024/0297212 A1
(43) Pub. Date: Sep. 5, 2024

(54) SEMICONDUCTOR DEVICE

(71) Applicant: DENSO CORPORATION, Kariya-city (JP)

(72) Inventors: Naoki TEGA, Kariya-city (JP); Yuichiro MATSUURA, Kariya-city (JP)

(21) Appl. No.: 18/663,327

(22) Filed: May 14, 2024

Related U.S. Application Data
(63) Continuation of application No. PCT/JP2022/024141, filed on Jun. 16, 2022.

(30) Foreign Application Priority Data
Dec. 20, 2021 (JP) 2021-206356

(51) Int. Cl. H01L 29/06; H01L 29/78

(52) U.S. Cl. CPC H01L 29/0607; H01L 29/7813

(57) ABSTRACT

A semiconductor device includes a semiconductor substrate, trenches extending in a first direction and arranged at intervals in a second direction intersecting the first direction, a gate insulating film, and a gate electrode. The semiconductor substrate includes a source region, a body region, a drift region, bottom regions, electric field relaxation regions, and contact regions. There are overlapping ranges in which each of inter-trench semiconductor regions and each of the electric field relaxation regions overlap each other, the overlapping ranges include contact overlapping ranges in which the contact regions are disposed and non-contact overlapping ranges in which the contact regions are not disposed, and the contact overlapping ranges and the non-contact overlapping ranges are alternately arranged in the first direction.

### CROSS REFERENCE TO RELATED APPLICATIONS

The present application is a continuation application of International Patent Application No. PCT/JP2022/024141 filed on Jun. 16, 2022, which designated the U.S. and claims the benefit of priority from Japanese Patent Application No. 2021-206356 filed on Dec. 20, 2021. The entire disclosures of all of the above applications are incorporated herein by reference.

### TECHNICAL FIELD

The present disclosure relates to a semiconductor device.

### BACKGROUND

Conventionally, there has been known a semiconductor device including a semiconductor substrate, trenches arranged at intervals on an upper surface of the semiconductor substrate, a gate insulating film covering an inner surface of each of the trenches, and a gate electrode disposed in each of the trenches. The semiconductor substrate includes a source region, a body region, a contact region, an electric field relaxation region, and a drift region.

### SUMMARY

A semiconductor device according to an aspect of the present disclosure includes: a semiconductor substrate; trenches provided from an upper surface of the semiconductor substrate, each extending in a first direction in the upper surface and being arranged at intervals in a second direction intersecting the first direction in the upper surface; a gate insulating film covering an inner surface of each of the trenches; and a gate electrode disposed in each of the trenches and insulated from the semiconductor substrate by the gate insulating film. The semiconductor substrate includes a source region, a body region, a drift region, bottom regions, electric field relaxation regions, and contact regions. The source region is an n-type region exposed on the upper surface of the semiconductor substrate and being in contact with the gate insulating film in each of the trenches. The body region is a p-type region being in contact with the gate insulating film in each of the trenches at a position below the source region. The drift region is an n-type region being in contact with the gate insulating film in each of the trenches at a position below the body region and is separated from the source region by the body region. Each of the bottom regions is a p-type region extending in the first direction so as to be in contact with the gate insulating film at a bottom surface of corresponding one of the trenches and being in contact with the drift region. The electric field relaxation regions are p-type regions disposed below the body region, connected to the body region, extending in the second direction, in contact with the bottom regions, and arranged at intervals in the first direction. Each of the contact regions is a p-type region exposed on the upper surface of the semiconductor substrate and in contact with the body region. Semiconductor regions located between the trenches are inter-trench semiconductor regions. There are overlapping ranges in which each of inter-trench semiconductor regions and each of the electric field relaxation regions overlap each other when the semiconductor substrate is viewed in plane from above, the overlapping ranges include contact overlapping ranges in which the contact regions are disposed and non-contact overlapping ranges in which the contact regions are not disposed, and the contact overlapping ranges and the non-contact overlapping ranges are alternately arranged in the first direction.

### BRIEF DESCRIPTION OF DRAWINGS

Objects, features and advantages of the present disclosure will become apparent from the following detailed description made with reference to the accompanying drawings. In the drawings:

FIG. 1 is a plan view of a semiconductor device according to a first embodiment;

FIG. 2 is a cross-sectional view taken along line II-II in FIG. 1;

FIG. 3 is a cross-sectional view taken along the line III-III in FIG. 1;

FIG. 4 is a plan view of a semiconductor device according to a second embodiment;

FIG. 5 is a cross-sectional view taken along line V-V in FIG. 4;

FIG. 6 is a plan view of a semiconductor device according to a third embodiment;

FIG. 7 is a cross-sectional view taken along line VII-VII in FIG. 6;

FIG. 8 is a cross-sectional view taken along line VIII-VIII in FIG. 6;

FIG. 9 is a cross-sectional view taken along line IX-IX in FIG. 6;

FIG. 10 is a cross-sectional view corresponding to FIG. 2 of a semiconductor device according to a fourth embodiment;

FIG. 11 is a cross-sectional view corresponding to FIG. 2 of a semiconductor device according to a fifth embodiment; and

FIG. 12 is a cross-sectional view corresponding to FIG. 2 of a semiconductor device according to a reference example.

### DETAILED DESCRIPTION

A semiconductor device according to a comparative example includes a semiconductor substrate, trenches arranged at intervals on an upper surface of the semiconductor substrate, a gate insulating film covering an inner surface of each of the trenches, and a gate electrode disposed in each of the trenches. The semiconductor substrate includes source regions of n-type, a body region of p-type, contact regions of p-type, electric field relaxation regions of p-type, and a drift region of n-type. Each of the source regions is exposed on the upper surface of the semiconductor substrate and is in contact with the gate insulating film. The body region is in contact with the gate insulating film at positions below the source regions. Each of the contact regions is exposed on the upper surface of the semiconductor substrate and is in contact with the source region and the gate insulating film. Each of the electric field relaxation regions is in contact with the gate insulating film at a position below the corresponding contact region. The drift region is in contact with the body region and the electric field relaxation regions from below. In the semiconductor device according to the comparative example, the source regions and the contact regions are alternately arranged along a direction in which the trenches extend.

When the semiconductor device according to the comparative example is turned off, a depletion layer extends from the body region and the electric field relaxation regions into the drift region. In the semiconductor device, since the contact regions are disposed at upper portions of the electric field relaxation regions, respectively, when the semiconductor device is turned off, holes quickly flow from the electric field relaxation regions to the contact regions, and a high reverse voltage is applied to a pn junction at interfaces between the electric field relaxation regions and the drift region. As a result, a depletion layer rapidly spreads in the drift region, and electric field concentration in the vicinities of the lower ends of the trenches is restricted.

However, in the semiconductor device according to the comparative example, since a large number of contact regions are arranged, the area of the source region exposed on the upper surface of the semiconductor substrate is reduced. As a result, the contact resistance of the source region increases.

A semiconductor device according to an aspect of the present disclosure includes: a semiconductor substrate; trenches provided from an upper surface of the semiconductor substrate, each extending in a first direction in the upper surface and being arranged at intervals in a second direction intersecting the first direction in the upper surface; a gate insulating film covering an inner surface of each of the trenches; and a gate electrode disposed in each of the trenches and insulated from the semiconductor substrate by the gate insulating film. The semiconductor substrate includes a source region, a body region, a drift region, bottom regions, electric field relaxation regions, and contact regions. The source region is an n-type region exposed on the upper surface of the semiconductor substrate and being in contact with the gate insulating film in each of the trenches. The body region is a p-type region being in contact with the gate insulating film in each of the trenches at a position below the source region. The drift region is an n-type region being in contact with the gate insulating film in each of the trenches at a position below the body region and is separated from the source region by the body region. Each of the bottom regions is a p-type region extending in the first direction so as to be in contact with the gate insulating film at a bottom surface of corresponding one of the trenches and being in contact with the drift region. The electric field relaxation regions are p-type regions disposed below the body region, connected to the body region, extending in the second direction, in contact with the bottom regions, and arranged at intervals in the first direction. Each of the contact regions is a p-type region exposed on the upper surface of the semiconductor substrate and in contact with the body region. Semiconductor regions located between the trenches are inter-trench semiconductor regions. There are overlapping ranges in which each of inter-trench semiconductor regions and each of the electric field relaxation regions overlap each other when the semiconductor substrate is viewed in plane from above, the overlapping ranges include contact overlapping ranges in which the contact regions are disposed and non-contact overlapping ranges in which the contact regions are not disposed, and the contact overlapping ranges and the non-contact overlapping ranges are alternately arranged in the first direction.

The semiconductor device described above has the overlapping ranges in which each of the inter-trench semiconductor regions and each of the electric field relaxation regions overlap each other when the semiconductor substrate is viewed in plane from above. The overlapping ranges include the contact overlapping ranges and the non-contact overlapping ranges. The contact overlapping ranges are ranges in which the contact region and each of the electric field relaxation regions overlap each other. That is, in this semiconductor device, each of the contact regions is disposed directly above the electric field relaxation regions. Therefore, when the semiconductor device is turned off, in the contact overlapping ranges, holes flow from the bottom regions to the contact regions via the electric field relaxation regions, and the bottom regions are maintained at a low potential. The contact overlapping ranges and the non-contact overlapping ranges are alternately arranged in the first direction in which the trenches extend. Since the contact overlapping ranges are distributed in this manner, the potential of the entire bottom region is stabilized at a low potential, and a depletion layer spreads from each of the bottom regions into the drift region in a well-balanced manner. Therefore, the electric field concentration in the vicinities of lower ends of the trenches can be restricted in a well-balanced manner. In addition, since the source region can be exposed on the upper surface of the semiconductor substrate in the non-contact overlapping ranges, the area of the source region can be secured. Since the contact overlapping ranges and the non-contact overlapping ranges are alternately arranged in the first direction in which the trenches extend, the area of the non-contact overlapping ranges (that is, the area of the source region on the upper surface of the semiconductor substrate) can be wide. Therefore, the contact resistance of the source region can be reduced.

Examples of technical elements disclosed in the present description are listed below. The following technical elements are useful independently.

In an embodiment disclosed in the present description, the overlapping ranges and the non-contact overlapping ranges may be alternately arranged in the second direction. In such a configuration, the electric field concentration in the vicinities of the lower ends of the trenches can be restricted in a more balanced manner, and the contact resistance of the source region can be reduced more uniformly.

In an embodiment disclosed in the present description, an upper drift region of n-type being in contact with the gate insulating film in each of the trenches at a position below the body region may be disposed between each of the electric field relaxation regions and the body region. In such a configuration, the upper drift region functions as a current path also in the ranges where the electric field relaxation regions are disposed. That is, the channel formed in the body region located above the electric field relaxation regions can be effectively used. Therefore, the channel resistance can be reduced.

In an embodiment disclosed in the present description, the electric field relaxation regions may be first electric field relaxation regions, the overlapping ranges may be first overlapping ranges, the contact overlapping ranges may be first contact overlapping ranges, and the non-contact overlapping ranges may be first non-contact overlapping ranges. The semiconductor substrate may further include second electric field relaxation regions of p-type. Each of the second electric field relaxation regions may be disposed below the body region, may be connected to the body region, may extend in a third direction intersecting the first direction and the second direction, and may be in contact with each of the bottom regions. The second electric field relaxation regions may be arranged at intervals in a direction intersecting the third direction. There may be second overlapping ranges in which each of the inter-trench semiconductor regions and each of the second electric field relaxation regions overlap each other when the semiconductor substrate is viewed in plane from above. The second overlapping ranges may include second contact overlapping ranges in which the contact regions are disposed and second non-contact overlapping ranges in which the contact regions are not disposed. The second contact overlapping ranges and the second non-contact overlapping ranges may be alternately arranged in the first direction.

In the above configuration, the first electric field relaxation regions and the second electric field relaxation regions are provided to extend in directions different from each other. Therefore, even when an interval between the first electric field relaxation regions and an interval between the second electric field relaxation regions are increased, the breakdown voltage of the semiconductor device can be ensured. Furthermore, since the interval between the electric field relaxation regions can be widened, the drift region can be disposed in a wide range in the inter-trench semiconductor regions, and the on-resistance can be reduced.

In an embodiment disclosed in the present description, the semiconductor device may further include an interlayer insulating film covering an upper surface of the gate electrode and having a contact hole above the upper surface of the semiconductor substrate, and an upper electrode covering a range extending over an upper surface of the interlayer insulating film and an inner surface of the contact hole, being in contact with the upper surface of the semiconductor substrate in the contact hole, and being insulated from the gate electrode by the interlayer insulating film. The upper electrode may include a tungsten-containing layer disposed inside the contact hole, and an aluminum-containing layer covering the upper surface of the interlayer insulating film and an upper surface of the tungsten-containing layer. In such a configuration, by disposing the tungsten-containing layer inside the contact hole, unevenness of the upper electrode (the aluminum-containing layer) caused by the contact hole can be reduced. In addition, since the tungsten-containing layer can densely fill the contact hole that is narrow, the semiconductor device can be miniaturized.

### First Embodiment

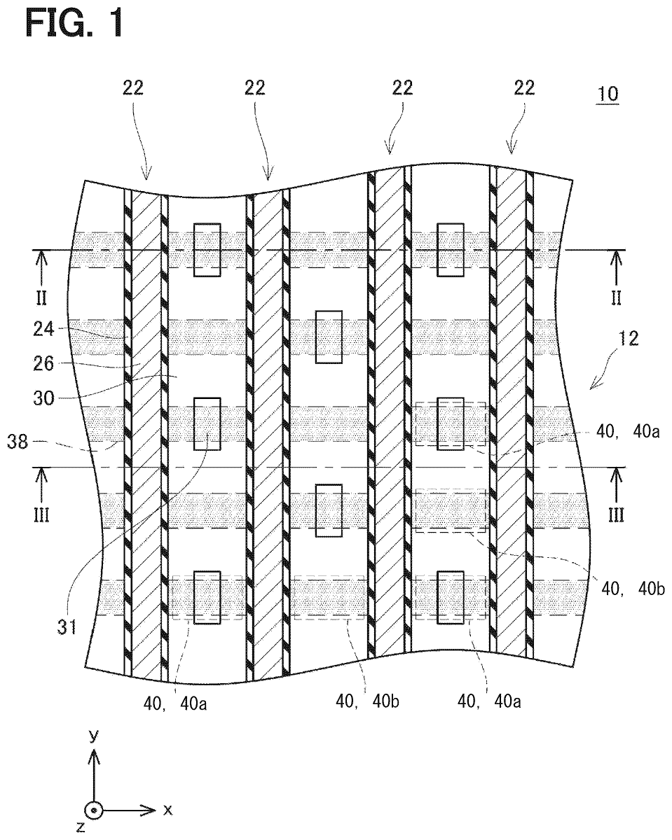

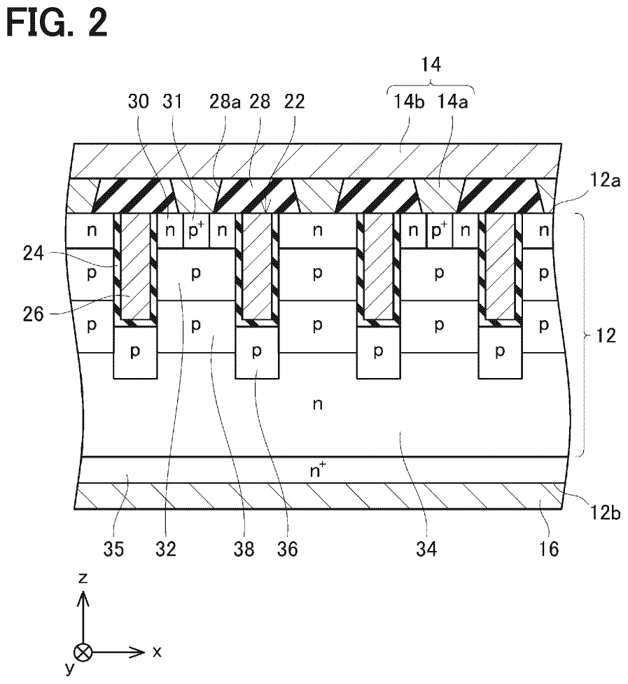

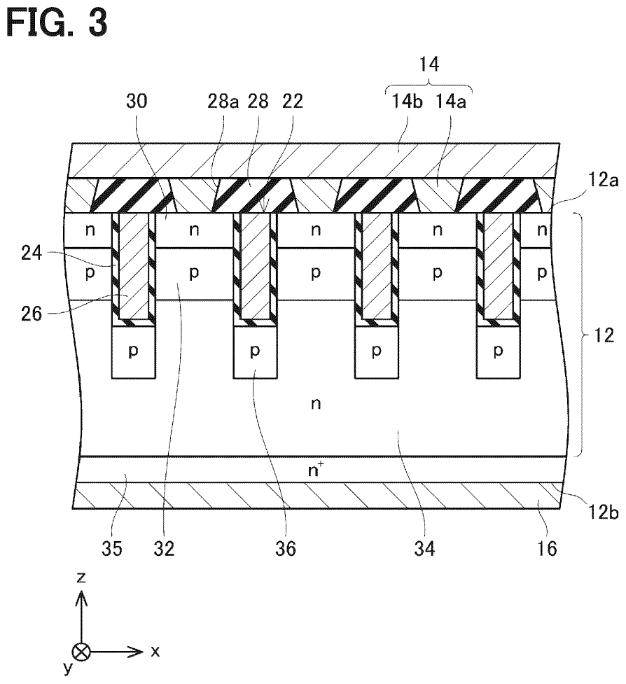

FIGS. 1 to 3 show a semiconductor device 10 according to a first embodiment. The semiconductor device 10 is a MOSFET (Metal-Oxide-Semiconductor Field-Effect Transistor). As shown in FIGS. 2 and 3, the semiconductor device 10 includes a semiconductor substrate 12, an upper electrode 14, and a lower electrode 16. In FIG. 1, illustration of an electrode layer and an insulating layer on the upper surface 12a of the semiconductor substrate 12 is omitted. The semiconductor substrate 12 is made of silicon carbide (SiC). However, the material of the semiconductor substrate 12 is not particularly limited, and may be another semiconductor material such as Si (silicon) or GaN (gallium nitride). In the following, a direction parallel to the upper surface 12a of the semiconductor substrate 12 may also be referred to as an x-direction, a direction parallel to the upper surface 12a and perpendicular to the x-direction may also be referred to as a y-direction, and a thickness direction of the semiconductor substrate 12 may also be referred to as a z-direction.

Multiple trenches 22 are provided from the upper surface 12a of the semiconductor substrate 12. The trenches 22 extend long along the y-direction. The trenches 22 extend parallel to each other. The trenches 22 are arranged at intervals in the x-direction. As shown in FIGS. 2 and 3, a gate insulating film 24 and a gate electrode 26 are disposed in each of the trenches 22. The gate insulating film 24 covers an inner surface of each of the trenches 22. The gate electrode 26 is disposed inside each of the trenches 22. The gate electrode 26 is insulated from the semiconductor substrate 12 by the gate insulating film 24.

As shown in FIGS. 2 and 3, an upper surface of the gate electrode 26 and the upper surface 12a of the semiconductor substrate 12 are covered with an interlayer insulating film 28. Multiple contact holes 28a are formed in the interlayer insulating film 28. Each of the contact holes 28a is provided in a range between the two adjacent trenches 22. That is, each of the contact hole 28a is disposed in a range where the gate electrode 26 is not provided in the x-direction. Each of the contact holes 28a penetrates from an upper surface to a lower surface of the interlayer insulating film 28.

The upper electrode 14 covers a range extending over an upper surface of the interlayer insulating film 28 and inner surfaces of the contact holes 28a. The upper electrode 14 includes a tungsten-containing layer 14a and an aluminum-containing layer 14b. The tungsten-containing layer 14a is disposed inside the contact holes 28a. The tungsten-containing layer 14a is in contact with the upper surface 12a of the semiconductor substrate 12 at bottoms of the contact holes 28a. The tungsten-containing layer 14a is formed such that an upper surface of the tungsten-containing layer 14a is substantially flat with respect to the upper surface of the interlayer insulating film 28. The tungsten-containing layer 14a is insulated from the gate electrode 26 by the interlayer insulating film 28. The aluminum-containing layer 14b covers substantially the entire region of the upper surface of the interlayer insulating film 28 and the upper surface of the tungsten-containing layer 14a. In the present embodiment, the tungsten-containing layer 14a is made of tungsten, and the aluminum-containing layer 14b is made of an alloy of aluminum and silicon. However, the tungsten-containing layer 14a may be a metal layer containing tungsten as a main component, and the aluminum-containing layer 14b may be a metal layer containing aluminum as a main component (including a simple substance of aluminum).

The lower electrode 16 is provided on a lower surface 12b of the semiconductor substrate 12. The lower electrode 16 is in contact with substantially the entire region of the lower surface 12b of the semiconductor substrate 12.

Inside the semiconductor substrate 12, a source region 30, multiple contact regions 31, a body region 32, a drift region 34, a drain region 35, multiple bottom regions 36, and a multiple electric field relaxation regions 38 are disposed.

The source region 30 is an n-type region. As shown in FIGS. 1 to 3, the source region 30 is disposed in each of semiconductor regions located between the adjacent trenches 22 (hereinafter referred to as inter-trench semiconductor regions). The source region 30 is disposed at a position exposed on the upper surface 12a of the semiconductor substrate 12, and is in ohmic contact with the upper electrode 14 (tungsten-containing layer 14a). The source region 30 is in contact with the gate insulating film 24 in the two trenches 22 located on both sides of the inter-trench semiconductor region.

The body region 32 is a p-type region. As shown in FIGS. 2 and 3, the body region 32 is disposed below the source region 30 and the contact region 31 described later. The body region 32 is in contact with the source region 30 and the contact region 31 from below. The body region 32 is in contact with the gate insulating film 24 in each of the trenches 22 at a position below the source region 30.

The drift region 34 is an n-type region. As shown in FIGS. 2 and 3, the drift region 34 is disposed below the body region 32 and the electric field relaxation region 38 described later. The drift region 34 is in contact with the body region 32 and the electric field relaxation region 38 from below. As shown in FIG. 3, the drift region 34 is in contact with the gate insulating film 24 in each of the trenches 22 at a position below the body region 32 in a range where the electric field relaxation region 38 is not disposed. The drift region 34 is distributed from each of the inter-trench semiconductor regions to a region below each of the trenches 22. The drift region 34 is separated from the source region 30 by the body region 32.

The drain region 35 is disposed below the drift region 34. The drain region 35 is an n-type region with higher n-type impurity concentration than the drift region 34. The drain region 35 is in contact with the drift region 34 from below. The drain region 35 is in ohmic contact with the lower electrode 16 on the lower surface 12b of the semiconductor substrate 12.

Each of the bottom regions 36 is a p-type region. Each of the bottom regions 36 is in contact with the gate insulating film 24 in each of the trenches 22 at a bottom surface of corresponding one of the trenches 22. Each of the bottom regions 36 extends long in the y-direction along the bottom surface of the corresponding of the trenches 22. The bottom regions 36 are in contact with the drift regions 34.

Each of the electric field relaxation regions 38 is a p-type region. As shown in FIG. 2, each of the electric field relaxation regions 38 is in contact with the body region 32 from below. In FIG. 1, each of the electric field relaxation regions 38 is indicated by gray hatching. As shown in FIG. 1, each of the electric field relaxation regions 38 extends long in a direction (the x-direction) intersecting each of the trenches 22. The electric field relaxation regions 38 are arranged at intervals in a direction (the y-direction) in which the trenches 22 extend. That is, as shown in FIG. 1, when the semiconductor substrate 12 is viewed in plane from above, the trenches 22 and the electric field relaxation regions 38 are arranged in a grid pattern. As shown in FIG. 2, each of the electric field relaxation regions 38 extends to a position lower than lower ends of the trenches 22 and is in contact with side surfaces of the bottom regions 36. Each of the bottom regions 36 extends to a position below each of the electric field relaxation regions 38. A side surface and a lower surface of each of the electric field relaxation regions 38 are surrounded by the drift region 34.

Each of the contact regions 31 is a p-type region. Each of the contact regions 31 has a p-type impurity concentration higher than that of the body region 32. As shown in FIGS. 1 and 2, each of the contact regions 31 is disposed in the inter-trench semiconductor region. Multiple contact regions 31 are disposed in each of the inter-trench semiconductor regions. Each of the contact regions 31 is exposed at the upper surface 12a of the semiconductor substrate 12 and is in ohmic contact with the upper electrode 14. As shown in FIG. 1, a side surface of each of the contact regions 31 is surrounded by the source region 30. As shown in FIG. 2, a lower surface of each of the contact regions 31 is in contact with the body region 32.

As described above, the upper end of each of the electric field relaxation regions 38 is connected to the body region 32. Thus, each of the bottom regions 36 is connected to the body region 32 via the electric field relaxation region 38. Therefore, each of the bottom regions 36 is connected to the upper electrode 14 via the electric field relaxation region 38, the body region 32, and the contact region 31. Therefore, the potential of each of the bottom regions 36 is substantially equal to the potential of the upper electrode 14.

As shown in FIG. 1, in the semiconductor device 10, when the semiconductor substrate 12 is viewed in plane from above, there are multiple overlapping ranges 40 (that is, gray-hatched regions) in which each of the inter-trench semiconductor regions and each of the electric field relaxation regions 38 overlap each other. Hereinafter, among the overlapping ranges 40, overlapping ranges 40 in which the contact regions 31 are disposed are referred to as contact overlapping ranges 40a, and overlapping ranges 40 in which the contact regions 31 are not disposed are referred to as non-contact overlapping ranges 40b. In the contact overlapping ranges 40a, the contact regions 31 are arranged so as to overlap the electric field relaxation regions 38. In the non-contact overlapping ranges 40b, the contact regions 31 are not disposed and the source region 30 is exposed to the upper surface 12a of the semiconductor substrate 12 in upper portion of the electric field relaxation regions 38. In the semiconductor device 10, the contact overlapping range 40a and the non-contact overlapping range 40b are alternately arranged in the direction (the y-direction) in which the trenches 22 extend. That is, the contact region 31 is arranged in every other overlapping range 40 in the y-direction. In addition, the contact overlapping range 40a and the non-contact overlapping range 40b are configured to be alternately arranged also in the direction (the x-direction) in which the electric field relaxation regions 38 extend. That is, the contact region 31 is arranged in every other overlapping range 40 in the x-direction.

When the semiconductor device 10 is used, a potential higher than that of the upper electrode 14 is applied to the lower electrode 16. When a voltage equal to or higher than a gate threshold value is applied to the gate electrode 26, a channel is formed in the body region 32 in a range in contact with the gate insulating film 24, and the semiconductor device 10 is turned on. When the voltage applied to the gate electrode 26 is lowered to less than the gate threshold value, the channel disappears and the semiconductor device 10 is turned off.

When the semiconductor device 10 is off, the potential of the lower electrode 16 is much higher than the potential of the upper electrode 14. In this state, the drift region 34 has a potential close to that of the lower electrode 16. As described above, the bottom region 36 has a potential substantially equal to that of the upper electrode 14. Therefore, a high reverse voltage is applied to a pn junction at an interface between the drift region 34 and the bottom region 36. Therefore, a depletion layer widely spreads from each of the bottom regions 36 into the drift region 34. As a result, electric field concentration in the vicinities of the lower ends of the trenches 22 is restricted, and the breakdown voltage of the semiconductor device 10 is ensured.

Next, an operation when the semiconductor device 10 is turned off will be described in detail. When the semiconductor device 10 is turned off and the potential of the lower electrode 16 rises, holes flow from the bottom region 36 to the upper electrode 14 through the electric field relaxation region 38, the body region 32, and the contact region 31. By the holes flowing in this manner, the potential of the bottom region 36 is maintained at a low potential. In the contact overlapping ranges 40a, a path of the holes from the bottom region 36 to the upper electrode 14 via the contact region 31 is short. As described above, the contact overlapping ranges 40a and the non-contact overlapping ranges 40b are alternately arranged in the x-direction and the y-direction. Therefore, the contact overlapping ranges 40a (that is, the contact regions 31) are arranged to be substantially uniformly dispersed on the upper surface of the semiconductor substrate 12. Also in the non-contact overlapping ranges 40b, a path from the bottom region 36 to the upper electrode 14 via the contact region 31 is not so long. Therefore, holes are quickly discharged from the bottom region 36 to the upper electrode 14 in the entire bottom regions 36. Thus, an increase in the potential of the bottom regions 36 due to an increase in the potential of the lower electrode 16 is restricted, and the potential of the bottom region 36 is maintained at substantially the same potential as the potential of the upper electrode 14. As a result, a depletion layer rapidly spreads around the bottom region 36, and electric field concentration in the vicinities of the lower ends of the trenches 22 is effectively restricted.

In the semiconductor device 10, the source region 30 is exposed on the upper surface 12a of the semiconductor substrate 12 in the non-contact overlapping ranges 40b. Since the contact overlapping range 40a and the non-contact overlapping ranges 40b are alternately arranged in the x-direction and the y-direction, the non-contact overlapping ranges 40b (that is, the area of the source region 30) can be secured, and the contact resistance between the source region 30 and the upper electrode 14 can be reduced.

In the first embodiment, the contact overlapping ranges 40a and the non-contact overlapping ranges 40b are alternately arranged in both the x-direction and the y-direction. However, the contact overlapping ranges 40a and the non-contact overlapping ranges 40b do not have to be alternately arranged in the x-direction. As long as the contact overlapping range 40a and the non-contact overlapping range 40b are alternately arranged at least in the y-direction, it is possible to achieve both the restriction of the electric field concentration in the vicinities of the lower ends of the trenches 22 and the reduction of the contact resistance of the source region 30. The same applies to other embodiments described below.

### Second Embodiment

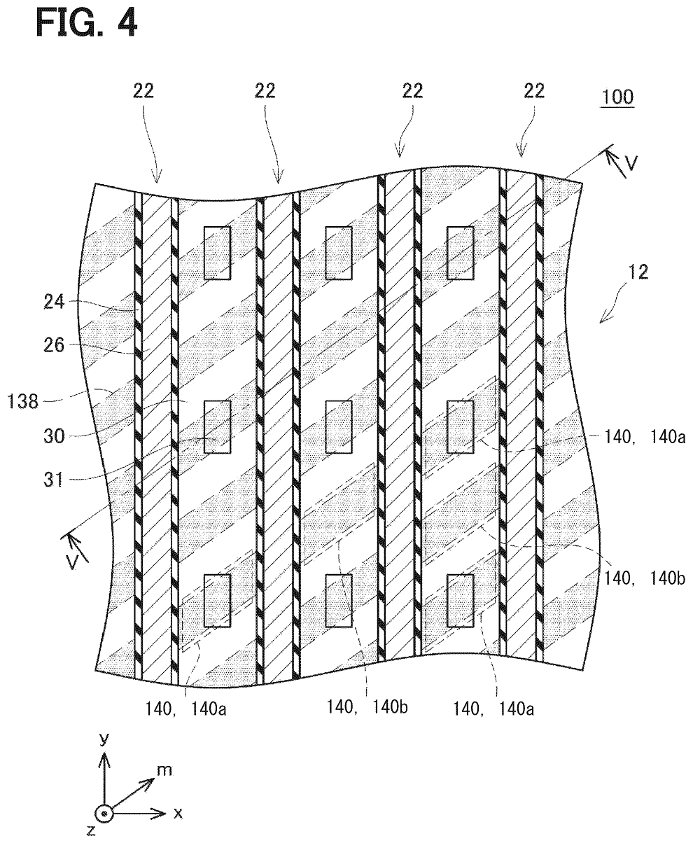

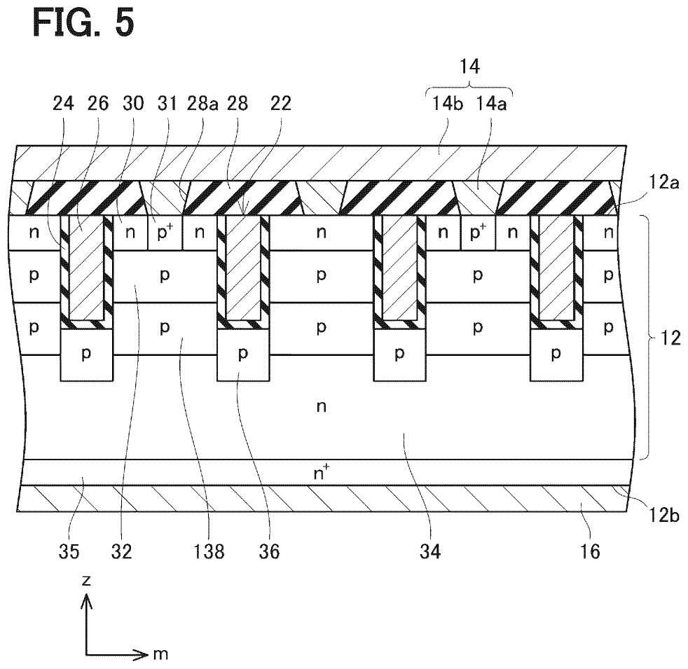

Next, a semiconductor device 100 according to a second embodiment will be described with reference to FIGS. 4 and 5. As shown in FIG. 4, in the semiconductor device 100 of the second embodiment, a direction in which each of electric field relaxation regions 138 extends is different from that of the first embodiment. Each of the electric field relaxation regions 138 extends long in an m-direction that intersects each of the trenches 22. The m-direction is a direction inclined by a predetermined angle with respect to a direction (the x-direction) orthogonal to a direction (the y-direction) in which each of the trenches 22 extends. As shown in FIG. 5, other configurations (the source region 30, the body region 32, the drift region 34, and the like) inside the semiconductor substrate 12 are the same as those in the first embodiment.

In the second embodiment, similarly to the first embodiment, contact overlapping ranges 140a and non-contact overlapping ranges 140b are alternately arranged in the direction (the y-direction) in which the trenches 22 extend. That is, the contact region 31 is arranged in every other overlapping range 140 in the y-direction. The contact overlapping ranges 140a and the non-contact overlapping ranges 140b are configured to be alternately arranged also in the direction (the m-direction) in which the electric field relaxation regions 138 extend. That is, the contact region 31 is disposed in every other overlapping range 140 in the m-direction. In the second embodiment, the contact overlapping ranges 140a and the non-contact overlapping ranges 140b are not alternately arranged in the x-direction. In the x-direction, the contact overlapping range 140a or the non-contact overlapping range 140b is continuously arranged with respect to each of the overlapping ranges 140.

Also in the present embodiment, since the contact overlapping ranges 140a and the non-contact overlapping ranges 140b are alternately arranged in the y-direction and the m-direction, it is possible to achieve both the restriction of the electric field concentration in the vicinities of the lower ends of the trenches 22 and the reduction of the contact resistance of the source region 30.

### Third Embodiment

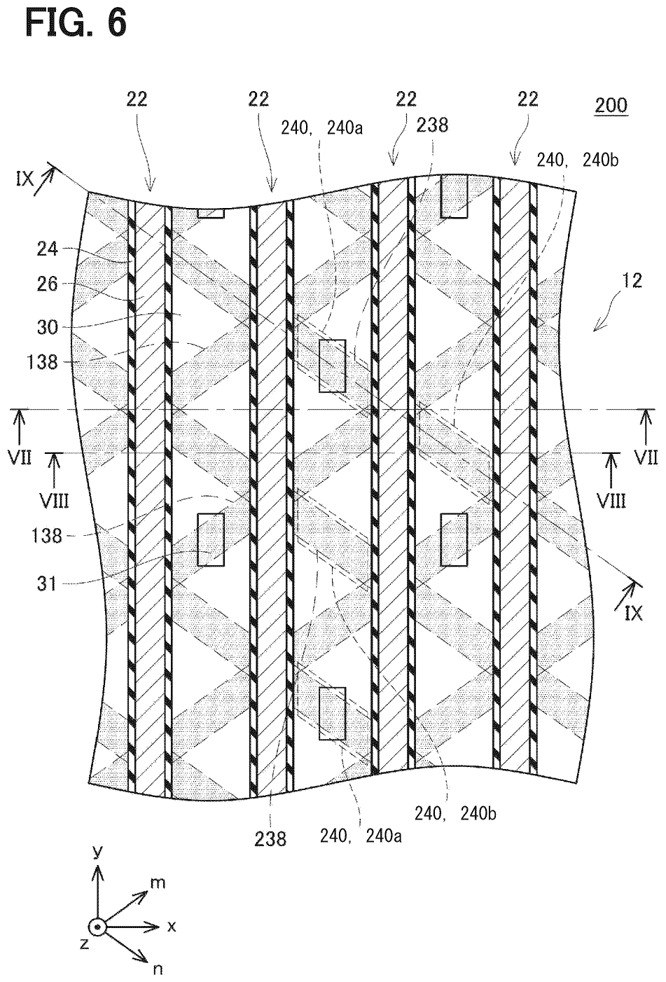

Next, a semiconductor device 200 according to a third embodiment will be described with reference to FIGS. 6 to 9. As shown in FIG. 6, in the semiconductor device 200 of the third embodiment, the semiconductor substrate 12 includes, in addition to the electric field relaxation regions 138 of the second embodiment (hereinafter, referred to as first electric field relaxation regions 138), second electric field relaxation regions 238 extending in a direction (the n-direction) different from that of the first electric field relaxation regions 138. The n-direction is a direction intersecting the direction (the y-direction) in which each of the trenches 22 extends and the direction (the m-direction) in which the first electric field relaxation regions 138 extend, and is a direction inclined by a predetermined angle with respect to the x-direction orthogonal to the y-direction.

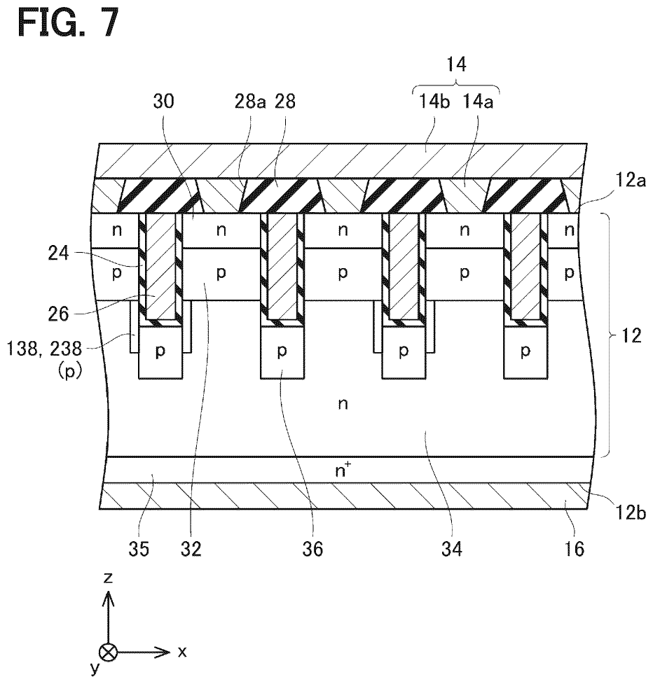

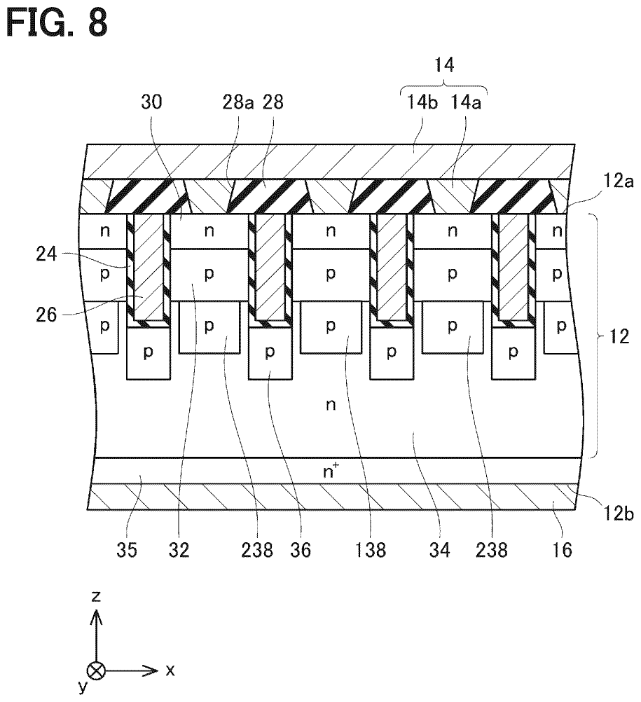

As shown in FIG. 6, when the semiconductor substrate 12 is viewed in plane from above, the first electric field relaxation regions 138 and the second electric field relaxation regions 238 intersect each other in ranges overlapping the trenches 22. As shown in FIG. 7, each of the first electric field relaxation regions 138 and each of the second electric field relaxation regions 238 are connected in a range in contact with the side surface of the trench 22. Each of the first electric field relaxation regions 138 and each of the second electric field relaxation regions 238 are in contact with the bottom region 36 in a range in which each of the first electric field relaxation regions 138 and each of the second electric field relaxation regions 238 are connected to each other. As shown in FIG. 8, in a cross section in which the first electric field relaxation regions 138 and the second electric field relaxation regions 238 are not connected, the drift region 34 is in contact with the side surface of each of the trenches 22 on the lower side of the body region 32.

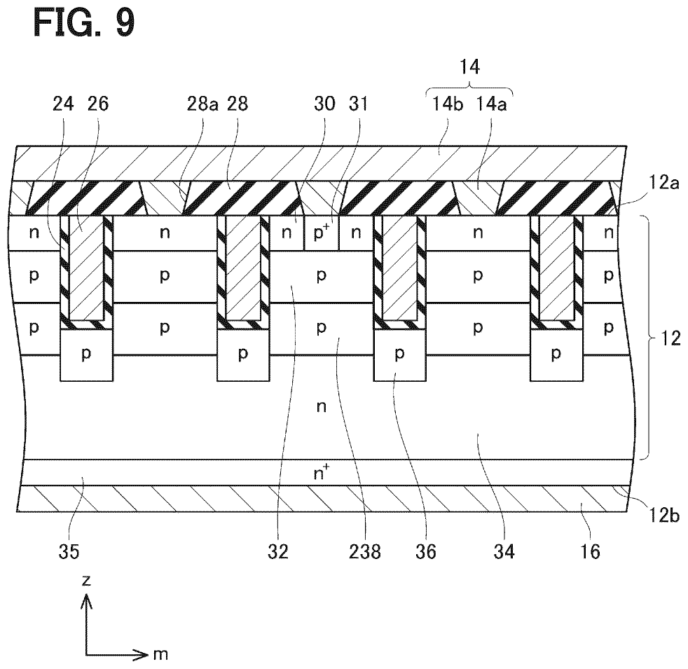

In the third embodiment, similarly to the first embodiment and the second embodiment, in the overlapping ranges 240 in which the inter-trench semiconductor regions and the second electric field relaxation regions 238 overlap each other, the contact overlapping ranges 240a and the non-contact overlapping ranges 240b are alternately arranged in the direction (the y-direction) in which the trenches 22 extend. That is, the contact region 31 is disposed in every other overlapping range 240 in the y-direction. In addition, as shown in FIG. 6 and FIG. 9, in the third embodiment, the contact overlapping range 240a is configured to be disposed at an interval (that is, not to be disposed continuously) with respect to each overlapping range 240 in the direction (the n-direction) in which the second electric field relaxation regions 238 extend.

In the semiconductor device 200 of the third embodiment, the first electric field relaxation regions 138 and the second electric field relaxation regions 238 are provided so as to extend in different directions (the m-direction and the n-direction). Therefore, even when the interval between the first electric field relaxation regions 138 and the interval between the second electric field relaxation regions 238 are increased, holes efficiently flow from the bottom region 36 to the contact region 31 via the electric field relaxation regions 138 and 238, and the breakdown voltage of the semiconductor device 200 can be secured. Furthermore, since the interval between the electric field relaxation regions 138 and 238 can be widened, the drift region 34 can be disposed in a wide range in the inter-trench semiconductor region, and the on-resistance can be reduced.

In the range where the electric field relaxation regions 138 and 238 are provided, the n-type drift region 34 is not in contact with the gate insulating film 24, and thus a current is less likely to flow through the channel formed in the body region 32. However, in the present embodiment, since the first electric field relaxation regions 138 and the second electric field relaxation regions 238 intersect in the ranges overlapping the trenches 22, electrons can flow from the channel formed in the body region 32 to the drift region 34 in a wide range. Therefore, an increase in on-resistance is restricted.

### Fourth Embodiment

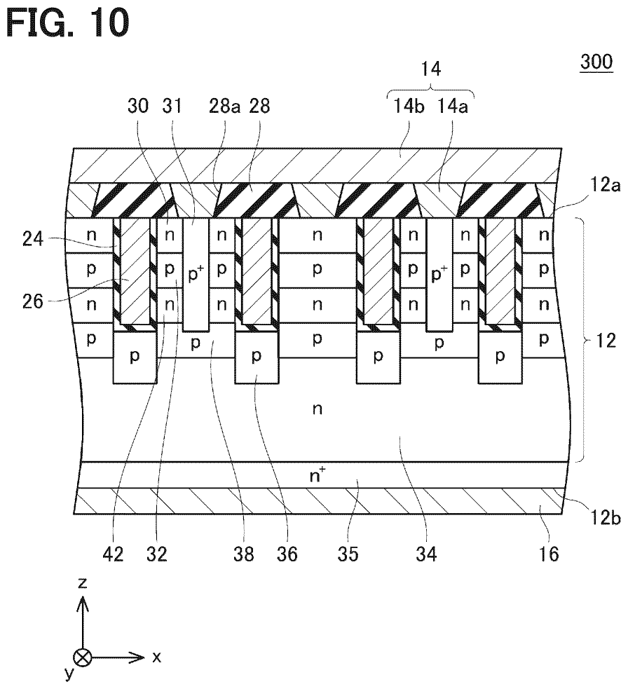

Next, a semiconductor device 300 according to a fourth embodiment will be described with reference to FIG. 10. FIG. 10 is a cross-sectional view corresponding to FIG. 2 of the first embodiment. In the fourth embodiment, an upper drift region 42 of n-type is disposed between the body region 32 and the electric field relaxation region 38. The upper drift region 42 is in contact with the body region 32 from below, and is in contact with the gate insulating film 24 at a position below the body region 32. The upper drift region 42 is separated from the source region 30 by the body region 32. The lower end of the upper drift region 42 is located above the lower end of each of the trenches 22. The electric field relaxation region 38 is disposed below the upper drift region 42. The electric field relaxation region 38 is in contact with the upper drift region 42 from below. Although not illustrated, the upper drift region 42 is connected to the drift region 34 in a cross section in which the electric field relaxation region 38 is not provided (cross section corresponding to FIG. 3 of the first embodiment).

In the semiconductor device 300 of the fourth embodiment, the upper drift region 42 functions as a current path also in the range where the electric field relaxation region 38 is provided. That is, the channel formed in the body region 32 located above the electric field relaxation region 38 (the channel formed in the cross section of FIG. 2) can be effectively used. Therefore, the channel resistance can be reduced.

### Fifth Embodiment

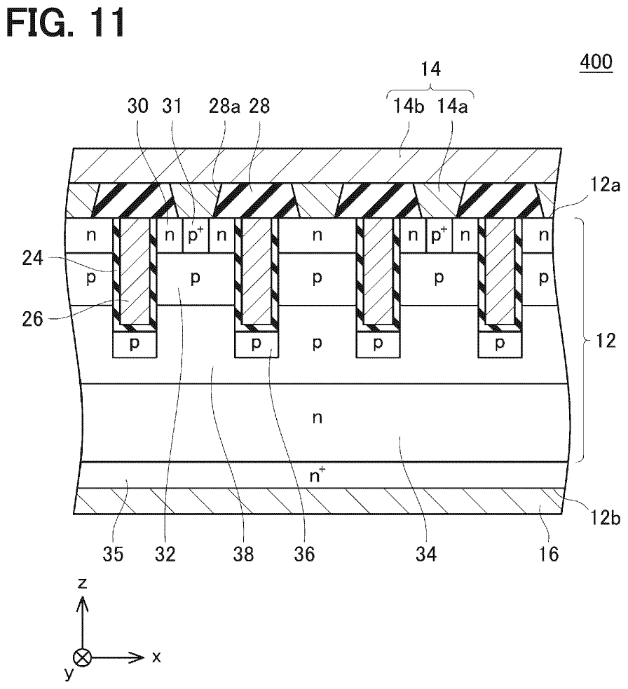

Next, a semiconductor device 400 according to a fifth embodiment will be described with reference to FIG. 11. FIG. 11 is a cross-sectional view corresponding to FIG. 2 of the first embodiment. In the fifth embodiment, a thickness (a length in the z-direction) of each of the bottom regions 36 is smaller than that in the first embodiment. In the fifth embodiment, the lower end of each of the bottom regions 36 is located above the lower end of each of the electric field relaxation regions 38. That is, in the range where the electric field relaxation region 38 is provided, each of the bottom regions 36 is not in contact with the drift region 34 and is surrounded by the electric field relaxation region 38.

In the semiconductor device 400 of the fifth embodiment, the thickness of the bottom regions 36 is smaller than that of the first embodiment. Since the distance of the bottom regions 36 protruding into the drift region 34 is short, electrons flowing through the inter-trench semiconductor region can flow into a wider range of the drift region 34, and the on-resistance can be reduced.

### Reference Example

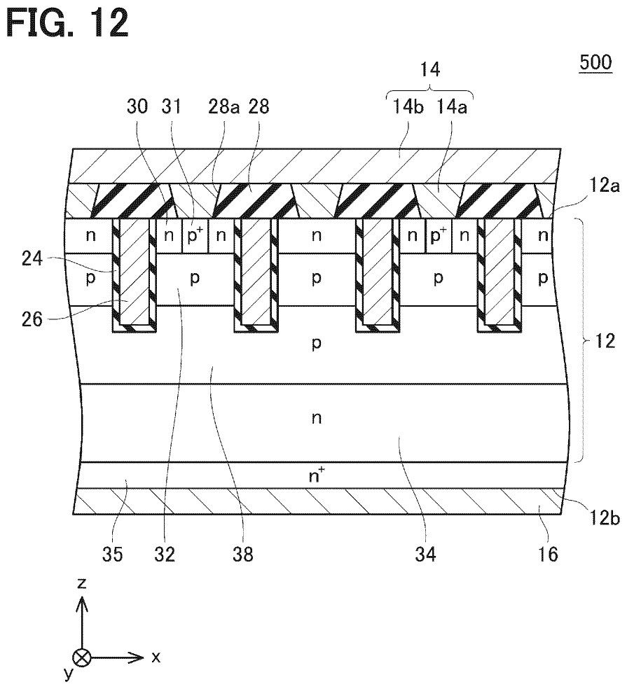

Next, a semiconductor device 500 of a reference example will be described with reference to FIG. 12. The semiconductor device 500 of the reference example is different from the semiconductor device 10 of the first embodiment in that the bottom regions 36 are not provided. The other configurations are similar to those of the first embodiment. In the semiconductor device 500 of the reference example, the bottom regions 36 are not provided. However, each of the electric field relaxation regions 38 extends to a position lower than the lower end of each of the trenches 22. Since the electric field relaxation regions 38 are provided at intervals in the direction (the y-direction) in which each of the trenches 22 extends, electric field concentration in the vicinities of the lower ends of the trenches 22 can be restricted by a depletion layer spreading from each of the electric field relaxation regions 38 into the drift region 34 in a state where the semiconductor device 500 is turned off. In the semiconductor device 500, since the bottom regions 36 are not formed, the number of manufacturing processes can be reduced.

Although the embodiments have been described in detail above, these are merely examples and do not limit the scope of claims. The techniques described in the claims include various modifications of the specific examples illustrated above. The technical elements described in the present description or the drawings exhibit technical usefulness alone or in various combinations, and are not limited to the combinations described in the claims at the time of filing. In addition, the techniques illustrated in the present description or drawings achieve objectives at the same time, and achieving one of the objectives itself has technical usefulness.

What is claimed is:

1. A semiconductor device comprising:
a semiconductor substrate;
trenches provided from an upper surface of the semiconductor substrate, each extending in a first direction in the upper surface, and arranged at intervals in a second direction intersecting the first direction in the upper surface;
a gate insulating film covering an inner surface of each of the trenches; and
a gate electrode disposed in each of the trenches and insulated from the semiconductor substrate by the gate insulating film, wherein
the semiconductor substrate includes:
a source region of n-type exposed on the upper surface of the semiconductor substrate and being in contact with the gate insulating film in each of the trenches;
a body region of p-type being in contact with the gate insulating film in each of the trenches at a position below the source region;
a drift region of n-type being in contact with the gate insulating film in each of the trenches at a position below the body region and separated from the source region by the body region;
bottom regions of p-type each extending in the first direction so as to be in contact with the gate insulating film at a bottom surface of corresponding one of the trenches and being in contact with the drift region;
electric field relaxation regions of p-type disposed below the body region, connected to the body region, extending in the second direction, being in contact with the bottom regions, and arranged at intervals in the first direction; and
contact regions of p-type each exposed on the upper surface of the semiconductor substrate and being in contact with the body region,
semiconductor regions located between the trenches are inter-trench semiconductor regions,
there are overlapping ranges in which each of the inter-trench semiconductor regions and each of the electric field relaxation regions overlap each other when the semiconductor substrate is viewed in plane from above,
the overlapping ranges include contact overlapping ranges in which the contact regions are disposed and non-contact overlapping ranges in which the contact regions are not disposed, and
the contact overlapping ranges and the non-contact overlapping ranges are alternately arranged in the first direction.

2. The semiconductor device according to claim 1, wherein
the contact overlapping ranges and the non-contact overlapping ranges are alternately arranged in the second direction.

3. The semiconductor device according to claim 1, wherein
an upper drift region of n-type being in contact with the gate insulating film in each of the trenches at a position below the body region is disposed between each of the electric field relaxation regions and the body region.

4. The semiconductor device according to claim 1, wherein
the electric field relaxation regions are first electric field relaxation regions,
the overlapping ranges are first overlapping ranges,
the contact overlapping ranges are first contact overlapping ranges,
the non-contact overlapping ranges are first non-contact overlapping ranges,
the semiconductor substrate further includes second electric field relaxation regions of p-type,
each of the second electric field relaxation regions is disposed below the body region, is connected to the body region, extends in a third direction intersecting the first direction and the second direction, and is in contact with each of the bottom regions,
the second electric field relaxation regions are arranged at intervals in a direction intersecting the third direction,
there are second overlapping ranges in which each of the inter-trench semiconductor regions and each of the second electric field relaxation regions overlap each other when the semiconductor substrate is viewed in plane from above,
the second overlapping ranges include second contact overlapping ranges in which the contact regions are disposed and second non-contact overlapping ranges in which the contact regions are not disposed, and
the second contact overlapping ranges and the second non-contact overlapping ranges are alternately arranged in the first direction.

5. The semiconductor device according to claim 1, further comprising:
an interlayer insulating film covering an upper surface of the gate electrode and having a contact hole above the upper surface of the semiconductor substrate; and
an upper electrode covering a range extending over an upper surface of the interlayer insulating film and an inner surface of the contact hole, being in contact with the upper surface of the semiconductor substrate in the contact hole, and being insulated from the gate electrode by the interlayer insulating film, wherein
the upper electrode includes:
a tungsten-containing layer disposed in the contact hole; and
an aluminum-containing layer covering the upper surface of the interlayer insulating film and an upper surface of the tungsten-containing layer.
